(19) United States
(12) Patent Application Publication
(10) Pub. No.: US 2013/0049192 A1
(43) Pub. Date: Feb. 28, 2013

(54) STACKED CHIP PACKAGE AND FABRICATION METHOD THEREOF

(71) Applicants: Hong-Dyi Chang, Hsinchu City (TW); Tai-Hung Lin, Hsinchu City (TW)

(72) Inventors: Hong-Dyi Chang, Hsinchu City (TW); Tai-Hung Lin, Hsinchu City (TW)

(21) Appl. No.: 13/591,225

(22) Filed: Aug. 22, 2012

(30) Foreign Application Priority Data
Aug. 25, 2011 (TW) 100130575

(51) Int. Cl. H01L 23/48; H01L 21/60

(52) U.S. Cl. 257/737; 438/109; 257/E23.021; 257/E21.506

(57) ABSTRACT

A semiconductor package for a stacked chip includes a first semiconductor chip, comprising a metal layer; a through-silicon-via, penetrating a top surface of the first semiconductor chip and electrically connected to the metal layer; a redistribution layer, formed on the top surface of the first semiconductor chip, and electrically connected to the through-silicon-via; and a second semiconductor chip, disposed on the first semiconductor chip and electrically connected to the first semiconductor chip via the redistribution layer.

### BACKGROUND OF THE INVENTION

1. Field of the Invention

The present invention relates to a stacked chip package and fabrication method for the same, and more particularly, to a stacked chip package utilizing a through-silicon-via and fabrication method for the same.

2. Description of the Prior Art

A Liquid Crystal Display (LCD) has the advantages of compactness, low power consumption, and low radiation, and has been widely applied to information products such as computer systems, mobile phones, personal digital assistants (PDAs), digital cameras, and tablet computers. A driving chip for an LCD display utilizes Chip-on-Glass (CoG) packaging to dispose the driving chip directly onto a glass substrate of the display, so as to minimize a required circuit area.

Please refer to FIGS. 1A and 1B, which are schematic diagrams of a cross-section and top-view, respectively, of a semiconductor package 10 according to the prior art. The semiconductor package 10 is used to implement a single-chip driving chip, having a driver circuit and static Random Access Memory (SRAM) circuit inside a layout block 100, and manufactured using the same semiconductor fabrication process. The semiconductor package 10 exchanges external signals via bumps BMP1-BMPn. This design results in larger circuit dimensions for the semiconductor package 10 (i.e. a large chip height Y1, as shown in FIG. 1B), which reduces a number of chips that can be cut out from a single wafer during fabrication, thus limiting the production capacity for manufacturers. Moreover, the single layout block 100 includes the driver circuit and memory circuit, and has a higher circuit complexity, which also limits the production yield rate. Furthermore, the large dimension of the layout block 100 prohibits a reduction of internal wire lengths, thus causing higher impedance values, lower transmission rate, parasitic capacitance, and higher power consumption.

Therefore, minimizing chip area and power consumption while increasing yield rate and transmission rate at the same time has become a common goal for the industry.

### SUMMARY OF THE INVENTION

The primary objective of the present invention is to provide a stacked chip package and fabrication method of the same.

The present invention discloses a semiconductor package for a stacked chip, comprising a first semiconductor chip which comprises: a metal layer; a through-silicon-via (TSV) penetrating a top surface of the first semiconductor chip, and electrically connected to the metal layer; a redistribution layer, formed on the top surface of the first semiconductor chip, and electrically connected to the TSV; and a second semiconductor chip, disposed on the first semiconductor chip, and connected to the first semiconductor chip via the redistribution layer.

The present invention further discloses a method for forming a semiconductor package for a stacked chip, the method comprising: forming a first semiconductor chip which comprises a metal layer; forming a through-silicon-via that penetrates a top surface of the first semiconductor chip, and is electrically connected to the metal layer; forming a redistribution layer, disposed on the top surface of the first semiconductor chip, and electrically connected to the through-silicon-via; and forming a second semiconductor chip on the first semiconductor chip, which is connected to the first semiconductor chip via the redistribution layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a cross-section view of a conventional stacked chip.

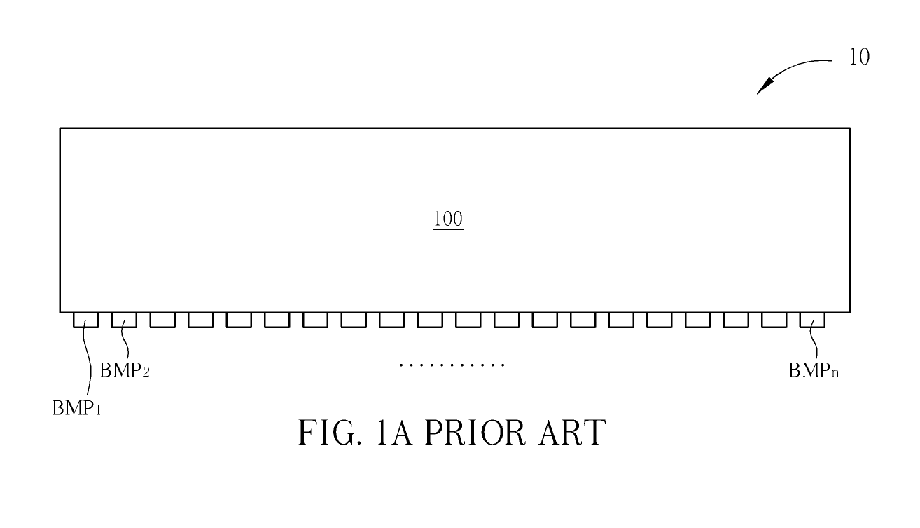

FIG. 1B is a schematic diagram of a top view of the stacked chip shown in FIG. 1A.

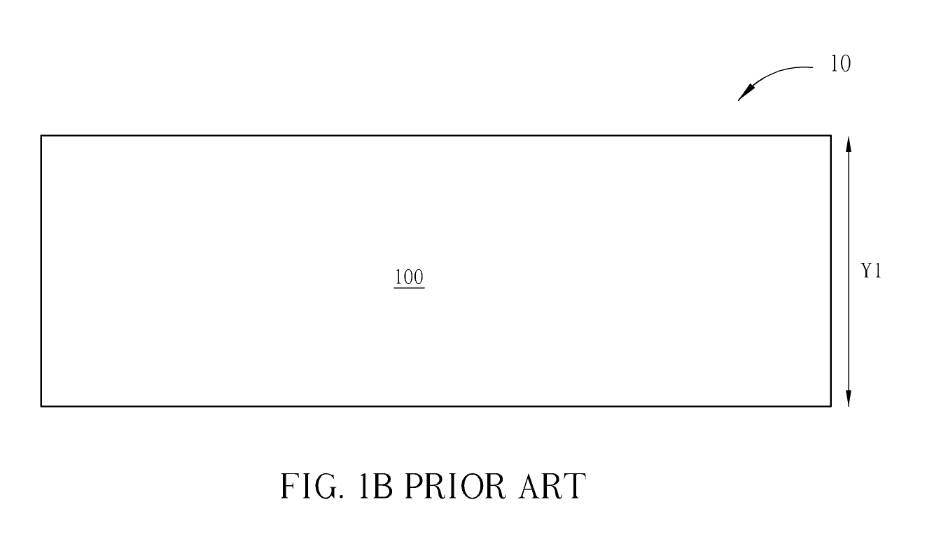

FIG. 2A is a schematic diagram of a cross-section view of a stacked chip according to an embodiment of the invention.

FIG. 2B is a schematic diagram of a top view of the stacked chip shown in FIG. 2A.

FIG. 3 is a schematic diagram of a process according to an embodiment of the invention.

### DETAILED DESCRIPTION

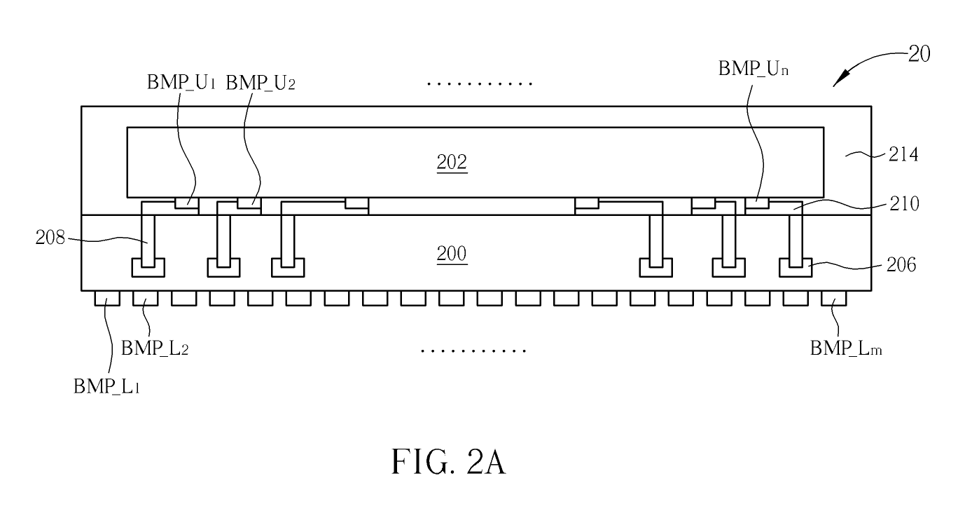

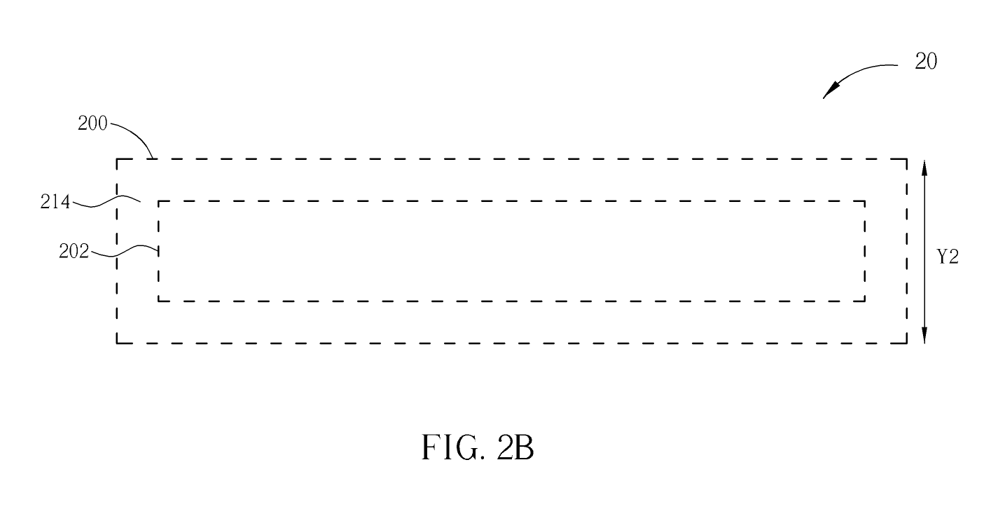

Please refer to FIGS. 2A and 2B, which are schematic diagrams of a cross-section and a top-view, respectively, of a semiconductor package 20 according to an embodiment of the present invention, respectively. As shown in FIG. 2A, the semiconductor package 20 may be used to implement a stacked chip, which is composed of a first semiconductor chip 200, a second semiconductor chip 202, a through-silicon-via (TSV) 208, a redistribution layer 210, and a package material 214. The first semiconductor chip 200 includes a metal layer 206 for laying out a driver circuit. The through-silicon-via 208 penetrates a top surface of the first semiconductor chip 200 and is electrically connected to the metal layer 206. Moreover, a plurality of bumps BMP_L1-BMP_Lm is formed on a lower surface of the first semiconductor chip 200, for connecting to an external device (not shown in FIGS. 2A and 2B). The redistribution layer 210 is formed on the top surface of the first semiconductor chip 200, for connecting the first semiconductor chip 200 and the second semiconductor chip 202. The second semiconductor chip 202 may be used as the layout of a static random access memory (SRAM) circuit, and is stacked on top of the first semiconductor chip 200. A plurality of bumps BMP_U1-BMP_Un is formed on a lower surface of the second semiconductor chip 202, for electrically connecting the metal layer 206 of the first semiconductor chip 200 via the redistribution layer 210 and the through-silicon-via 208. The package material 214 encloses the second semiconductor chip 202, and is used for enhancing an overall chip strength of the semiconductor package 20.

Furthermore, as shown in FIG. 2B, a chip height of the semiconductor package 20 is Y2. Compared with the conventional semiconductor package 10, the semiconductor package 20 has a smaller circuit area (i.e. the chip height Y2 of the semiconductor package 20 is smaller than the chip height Y1 of the semiconductor package 10), and the first semiconductor chip 200 and the second semiconductor chip 202 may be manufactured using different semiconductor fabrication processes to increase yield rate and production capacity.

Please note that FIGS. 2A and 2B only illustrate a concept of the invention, and alterations and modifications maybe made by those skilled in the art. For example, the semiconductor package 20 may be a Chip-on-Glass (CoG) driving chip, wherein the driver circuit and static random access memory (SRAM) circuit may be disposed on the first semiconductor chip 200 and the second semiconductor chip 202, respectively. In such a case, the first semiconductor chip 200 and the second semiconductor chip 202 may be manufactured using different semiconductor fabrication processes, respectively. For example, the first semiconductor chip 200 for disposing the driver circuit may be manufactured using a lower level semiconductor fabrication process, and the second semiconductor chip 202 for disposing the memory circuit maybe manufactured using a higher level semiconductor fabrication process. As such, compared with the semiconductor package 10, circuit areas for both of the first semiconductor chip 200 and the second semiconductor chip 202 may be reduced (e.g. reduced by 40-50% of the semiconductor package 10), allowing a higher number of chips to be cut out from a single wafer during fabrication (e.g. increased by 70-100%), thereby greatly improving production capacity. Furthermore, since the driving portion and the memory portion of the driving chip are split into two independent chips manufactured separately, circuit complexity of the semiconductor package 20 will be lower than that of the semiconductor package 10, thereby enhancing the fabrication yield rate. Moreover, by being split into the first semiconductor chip 200 and the second semiconductor chip 202, the semiconductor package 20 may be fabricated using two parallel pipelines, thereby enhancing production speed.

The through-silicon-via 208 and the redistribution layer 210 are used for connecting the first and second semiconductor chips 200 and 202, and should preferably exhibit a low impedance value. In this way, wire length and connection resistance may be effectively reduced in the semiconductor package 20, thereby reducing chip area and increasing data transmission rate, as well as providing other advantages such as smaller form factor, higher efficiency, low power consumption, and lower costs. Bumps BMP_L1-BMP_Lm formed on the lower surface of the first semiconductor chip 200 may be copper, nickel, gold, or their alloy. The bumps BMP_U1-BMP_Un formed on the lower surface of the second semiconductor chip 202 may be Flip-Chip bumps, solder bumps, micro bumps or copper pillar bumps, but are not limited thereto, and those skilled in the art may perform alterations or variations accordingly. Moreover, the package material 214 may be formed utilizing methods such as fan-out package or chip die saw, to enhance an overall chip strength of the semiconductor package 20 and the final stacked chip product.

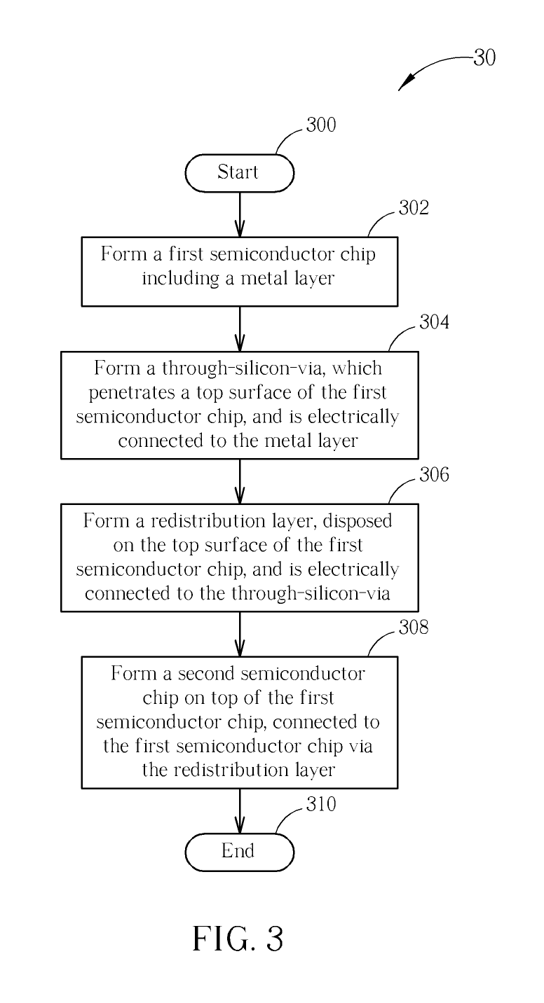

The above procedures for forming the semiconductor package 20 may be further summarized into a semiconductor package-forming process 30, as shown in FIG. 3. The semiconductor package-forming process 30 includes the following steps:

Step 300: Start;

Step 302: Form the first semiconductor chip 200 including the metal layer 206;

Step 304: Form a through-silicon-via 208, which penetrates a top surface of the first semiconductor chip 200, and is electrically connected to the metal layer 206;

Step 306: Form a redistribution layer 210, disposed on the top surface of the first semiconductor chip 200, and electrically connected to the through-silicon-via 208;

Step 308: Form a second semiconductor chip 202 on top of the first semiconductor chip 200, connected to the first semiconductor chip 200 via the redistribution layer 210;

Step 310: End.

Details of the semiconductor package forming process 30 may be found in the above, and are therefore not repeated here.

Please note that the primary spirit of the invention is to split a chip into an upper and lower semiconductor chip, connected together via a through-silicon-via and redistribution layer to form a stacked chip. Variations made accordingly are within the scope of the invention. For example, the semiconductor package 20 is not limited to being split into the first semiconductor chip 200 and the second semiconductor chip 202, but may also be split into three or more semiconductor chips, providing that the chips may be mutually connected via the through-silicon-via and the redistribution layer to achieve a smaller circuit area, higher transmission rate, and lower power consumption. Furthermore, in the above-mentioned embodiment, the semiconductor package 20 is split into the driving portion and the memory portion according to circuit function(s), but may also be split indifferent ways, as long as the particular way contributes to utilization of different fabrication processes to manufacture each portion separately for achieving higher production capacity or yield rate, or a lower production complexity. Moreover, the fabrication processes for the semiconductor package 20 are not limited to the above, and those skilled in the art may make variations accordingly. For example, the first semiconductor chip 200 and the second semiconductor chip 202 may be cut from a same wafer or different wafers, to achieve a higher heterogeneous integration. The bumps BMP_L1-BMP_Lm and bumps BMP_U1-BMP_Un are not limited to being formed from the aforementioned materials, as long as the material used provides a lower impedance value, higher transmission rate, and other characteristics conducive to the integration of the stacked chip.

In summary, the semiconductor package of the invention splits a driving chip into two different chips manufactured using different respective semiconductor fabrication processes, which are combined to form a stacked chip. As such, it is possible to obtain a smaller circuit area, higher transmission rate, and low power consumption, and also achieve a higher yield rate and production capacity during fabrication.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package for a stacked chip, comprising:
a first semiconductor chip, comprising a metal layer;
a through-silicon-via (TSV), penetrating a top surface of the first semiconductor chip, and electrically connected to the metal layer;
a redistribution layer, formed on the top surface of the first semiconductor chip, and electrically connected to the TSV; and
a second semiconductor chip, disposed on the first semiconductor chip, and connected to the first semiconductor chip via the redistribution layer.

2. The semiconductor package of claim 1, wherein the stacked chip is a Chip-on-Glass (CoG) chip.

3. The semiconductor package of claim 1, wherein the second semiconductor chip is electrically connected to the redistribution layer via a plurality of bumps, for connecting to the first semiconductor chip.

4. The semiconductor package of claim 3, wherein the plurality of bumps are flip-Chip bumps, solder bumps, micro bumps, or copper pillar bumps.

5. The semiconductor package of claim 1, wherein the first semiconductor chip further comprises a plurality of bumps, formed on a lower surface of the first semiconductor chip, for connecting to an external device.

6. The semiconductor package of claim 5, wherein the plurality of bumps of the first semiconductor chip are formed from copper, nickel, gold, or an alloy thereof.

7. The semiconductor package of claim 1, wherein the first semiconductor chip and the second semiconductor chip are manufactured using different semiconductor fabrication processes.

8. The semiconductor package of claim 1 further comprising a package material enclosing the second semiconductor chip.

9. A method for forming a semiconductor package for a stacked chip, the method comprising:
forming a first semiconductor chip, comprising a metal layer;
forming a through-silicon-via, penetrating a top surface of the first semiconductor chip, and electrically connected to the metal layer;
forming a redistribution layer, disposed on the top surface of the first semiconductor chip, and electrically connected to the through-silicon-via; and
forming a second semiconductor chip on the first semiconductor chip, connected to the first semiconductor chip via the redistribution layer.

10. The method of claim 9, wherein the stacked chip is a Chip-on-Glass (CoG) chip.

11. The method of claim 9, wherein forming the second semiconductor chip comprises forming a plurality of bumps for the second semiconductor chip to be electrically connected to the redistribution layer via the plurality of bumps, so as to be connected to the first semiconductor chip.

12. The method of claim 11, wherein the plurality of bumps are Flip-Chip bumps, Solder bumps, Micro bumps, or Copper pillar bumps.

13. The method of claim 9, wherein the first semiconductor chip further comprises a plurality of bumps, formed on a lower surface of the first semiconductor chip, for connecting to an external device.

14. The method of claim 13, wherein the plurality of bumps of the first semiconductor chip are formed from copper, nickel, gold, or an alloy thereof.

15. The method of claim 9, wherein the first semiconductor chip and the second semiconductor chip are manufactured using different semiconductor fabrication processes.

16. The method of claim 9, wherein the semiconductor package further comprises a package material, enclosing the second semiconductor chip.
